(19) United States
(12) Patent Application Publication
(10) Pub. No.: US 2006/0125511 A1
(43) Pub. Date: Jun. 15, 2006

(54) Image test method, program thereof and recording medium storing the program

(75) Inventor: Shinichi Tsukagoshi, Adumino (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/295,549

(22) Filed: Dec. 7, 2005

(30) Foreign Application Priority Data
Dec. 15, 2004 (JP) 2004-362728

(51) Int. Cl. G01R 31/00

(52) U.S. Cl. 324/770

(57) ABSTRACT

An image test method for a game machine display device provided with a display unit that displays a predetermined image, a game image information storing unit that stores game image information, a control unit that instructs the display unit to display a game image based on the game image information, and a test program storing unit that stores an image test program for testing the game image displayed on the display unit, the test program storing unit storing test image information for testing the game image displayed on the display unit in addition to the image test program, the method under the control of the control unit including the steps of: inputting a control command to start a test of an image; reading out the test image information from the test program storing unit; and displaying the test image based on the test image information on the display unit.

The entire disclosure of Japanese Patent Application No. 2004-362728, filed Dec. 15, 2004, is expressly incorporated by reference herein.

### BACKGROUND

1. Technical Field

The present invention relates to an image test method, a program thereof, and a recording medium storing the program.

2. Related Art

In game machines such as pachinko machines (Japanese upright pinball game machines), there has been known the one provided with a main control unit that controls the whole game machine, a display control unit that instructs a display unit to display a predetermined image in response to a control command given by the main control unit, and a ROM (hereinafter, referred to as a display memory) that stores various pieces of game image information such as pictures (for instance, see Document 1: JP-A-2004-81816).

According to the game machine disclosed in Document 1, in response to the control command given by the main control unit, the display control unit reads out the predetermined game image information from the display memory, instructs the display unit to display three reels of a left reel, a right reel and a central reel, and changes the pictures of the reels respectively in conjunction with a hit prize of a ball caused by entering a predetermined hit prize gate.

In recent years, the game image displayed on the display unit attracts game players to the game machines not only by the kind and motion of the pictures, but also by the display of different presentation patterns in which, for instance, background images and colors vary and desirable character images appear.

Incidentally, in such game machines, it is necessary to test whether or not partial color lacking or color deterioration is found on the background image and displayed pictures of the game image displayed on the display unit in order to display the game image effectively with the above-stated various presentation patterns.

For instance, the following method is conceivable as an image test method for testing the displayed colors of the game image displayed on the display unit.

First, a test program memory is provided in the game machine, the test program memory storing an image test program that instructs the display unit to display a test image (color bar etc.) of the displayed colors of the game image. Herein, test image information for the test image is typically stored in the display memory together with the game image information. In response to a test start command given by the main control unit, the display control unit reads out the test image information stored in the display memory according to the image test program stored in the test program memory, and instructs the display unit to display the test image based on the test image information. An operator tests whether or not the partial color lacking or the color deterioration is found on the background image and displayed pictures of the game image displayed on the display unit by checking the test image displayed on the display unit, for example, with eyes.

However, with the above-described image test method, since the test image information is stored in the display memory, which causes the storage address of the test image information stored in the display memory to be changed when the various pieces of game image information stored in the display memory are changed, the image test program must be corrected.

Owing to this, the production of the image test program might be complicated.

### SUMMARY

An advantage of some exemplary aspects of the invention is to provide an image test method that realizes easy production of an image test program, a program thereof, and a recording medium storing the program.

An image test method according to an aspect of the invention for a game machine display device provided with a display unit that displays a predetermined image, a game image information storing unit that stores game image information, a control unit that instructs the display unit to display a game image based on the game image information, and a test program storing unit that stores an image test program for testing the game image displayed on the display unit. The test program storing unit stores test image information for testing the game image displayed on the display unit in addition to the image test program. The method under the control of the control unit includes the steps of: inputting a control command to start a test of an image; reading out the test image information from the test program storing unit; and displaying the test image based on the test image information on the display unit.

According to the aspect of the invention, the test image information is stored in the test program storing unit of the game machine display device. The control unit inputs the control command to start the test of the image and then recognizes the control command. In addition, in response to the recognized control command and according to the image test program, the control unit reads out the test image information from the program storing unit, and instructs the display unit to display the test image based on the read test image information.

Accordingly, the game image information is stored in the game image information storing unit while the test image information is stored in the test program storing unit, so that the storage location of the game image information is independent from that of the test image information. Therefore, even when the game image information is modified, the storage address of the test image information will not be changed, and consequently, the image test program need not be corrected. In addition, since the game image information can independently be produced from the image test program, when a new model game machine is developed, the image test program can be developed before the production of the game image information is completed. Therefore, with the image test method of the aspect of the invention, the image test program can easily be produced.

Further, since the storage location of the game image information is independent from that of the test image information, the storage address of the game image information will not be changed even when the test image information is additionally provided or modified, so that it is not necessary to correct the control program for instructing the display unit to display the game image based on the game image information.

Incidentally, in a case where the game image information storing unit is a CGROM (Read Only Memory) etc. and the test program storing unit that stores the image test program is a program ROM etc., since the game image information and the test image information have been stored in the same CGROM in typical machines, the following preparation procedures are necessary for performing the image test for the game machine display device of the respective models having different kinds of game image information.

First, the test image information is stored in each CGROM of the respective models.

At this time, because the respective models have the different kinds of game image information, the storage address of each test image information varies among the respective models. Therefore, image test programs corresponding to the respective models are produced and stored in the program ROMs, respectively.

Meanwhile, with the aspect of the invention, since the storage location of the game image information is independent from that of the test image information, preparing the program ROM storing the test image information and the image test program only for one model is enough to perform the image test of the game machine display devices of the respective models, simply by replacing the program.

Preferably, in the above-described image test method, the test image information may be contracted image information in which the number of pixels of the test image is contracted, and in displaying, the control unit may enlarge the contracted image information and controls the display unit to display the test image.

With this configuration, the test image information is the contracted image information in which the number of pixels of the test image is contracted. And, when the test image information is displayed on the display unit in the step of displaying, the control unit enlarges the contracted image information. Accordingly, the size of the test image information can be decreased, and thus the capacity of the test program storing unit need not be increased. In addition, by decreasing the size of the test image information, the test image information can be transmitted smoothly, thereby quickly displaying the test image on the display unit.

An image test program according to another aspect of the invention for a game machine display device provided with a display unit that displays a predetermined image, a game image information storing unit that stores game image information, a control unit that instructs the display unit to display a game image based on the game image information. The program instructs the control unit of the above-described game machine display device to execute the above-described image test method.

According to the aspect of the invention, by installing the image test program in the test program storing unit of the game machine display device, the above-described image test method can be performed with the instruction of the control unit of the game machine display device, so that the same effects and advantages can be obtained as the above-described image test method, and the usage of the aspect of the invention can remarkably be promoted.

A recording medium according to yet another aspect of the invention stores the above-described image test program readably by a computing unit.

According to the aspect of the invention, since the image test program for performing the above-described image test method is stored in the recording medium, not only the same effects and advantages can be obtained as the above-described image test method as well as the image test program, but also the program can easily be handled so as to remarkably promote the usage of the aspect of the invention.

### BRIEF DESCRIPTION OF THE DRAWINGS

The invention will be described with reference to the accompanying drawings, wherein like numbers reference like elements.

FIG. 1 is a block diagram showing the brief configuration of a pachinko machine as a game machine according to the present exemplary embodiment;

FIGS. 2A to 2E are illustrations respectively showing examples of test image of the aforesaid embodiment;

FIGS. 3A and 3B are illustrations respectively showing examples of test image information stored in a test program ROM of the aforesaid embodiment;

FIGS. 4A and 4B are illustrations respectively showing examples of the test image information stored in the test program ROM of the aforesaid embodiment;

FIGS. 5A and 5B are illustrations respectively showing examples of the test image information stored in the test program ROM of the aforesaid embodiment;

FIGS. 6A and 6B are illustrations respectively showing examples of the test image information stored in the test program ROM of the aforesaid embodiment;

FIG. 7 is a schematic illustration showing an example of the configuration of a display buffer of the aforesaid embodiment; and

FIG. 8 is a flowchart explaining an image test method for a variable display device of the aforesaid embodiment.

### DESCRIPTION OF EXEMPLARY EMBODIMENT(S)

An exemplary embodiment of the invention will be described below with reference to attached drawings.

Brief Configuration of Pachinko Machine

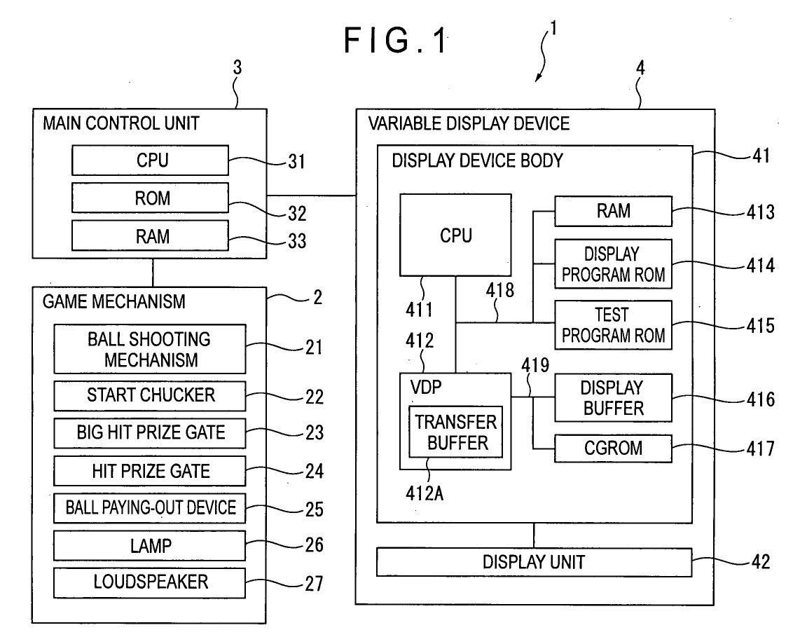

FIG. 1 is a block diagram showing the brief configuration of a pachinko machine 1 as a game machine according to the present exemplary embodiment.

The pachinko machine 1 is the one that provides a “big hit prize” by a lottery with a predetermined probability, which can display thereon a game image (hereinafter, referred to as an animation) with various presentation patterns in which the display state is changed, and a test image for testing the displayed colors and the like of the animation. As shown in FIG. 1, the pachinko machine 1 includes a game mechanism 2, a main control unit 3, and a variable display device 4 as a game machine display machine.

The game mechanism 2 has a play board (not shown), a ball shooting mechanism 21, a start chucker 22, a big hit prize gate (attacker) 23, a hit prize gate 24, a ball paying-out device 25, a lamp 26 and a speaker 27.

Though not shown, provided in the play board are not only a plurality of nails and pinwheels for guiding the game ball but also the start chucker 22, the big hit prize gate 23, the hit prize gate 24 and a display unit (described later) of the variable display device 4, respectively arranged on predetermined positions of a surface (a playfield) thereof.

The ball shooting mechanism 21 shoots the game ball toward the surface of the play board under that control of the main control unit 3. The ball shooting mechanism 21 mainly consists of a rotatably operable shooting handle, and a shooting motor that shoots the game ball corresponding to a rotation angle of the shooting handle. Then, a signal corresponding to the rotation angle is output from the shooting handle to the main control unit 3, so that the shooting motor is controlled by the main control unit 3.

The big hit prize gate 23 is opened by the main control unit 3 in conjunction with the display content (hit pattern) displayed on the display unit (described later) of the variable display device 4. And, the big hit prize gate 23 outputs a predetermined signal to the main control unit 3 when the game ball enters the gate.

The ball paying-out device 25 pays out a predetermined number of game balls when the game ball enters the start chucker 22, the big hit prize gate 23 and the hit prize gate 24 under the control of the main control unit 3.

The lamp 26 is lighted and/or blinked in conjunction with the play state under the control of the main control unit 3.

The speaker 27 outputs various kinds of sounds in conjunction with the play state under the control of the main control unit 3.

The main control unit 3 includes a CPU (Central Processing Unit) 31, a ROM 32, a RAM (Random Access Memory) 33, and the like.

The ROM 32 stores a control program for entirely controlling the pachinko machine 1 and various pieces of control data, the control program and the control data being processed by the CPU 31.

The RAM 33 temporarily stores data and program necessary for the operation of the CPU 31.

The CPU 31 executes various kinds of processing according to the control program stored in the ROM 32 in response to the signal output from the ball shooting mechanism 21, the start chucker 22, the hit prize gate 24 and the like. Then, the CPU 31 controls the operation of the game mechanism 2. Additionally, the CPU 31 outputs a control command (a presentation start command giving an instruction “to display the animation with the predetermined presentation pattern” or a test start command giving an instruction “to display the predetermined test image”) to the variable display device 4, so that the variable display device 4 displays the animation with the predetermined presentation pattern or the predetermined test image.

The variable display device 4 displays the animation with the predetermined presentation pattern or the predetermined test image in response to the control command given by the main control unit 3. As shown in FIG. 1, the variable display device 4 includes a display device body 41 and a display unit 42.

The display device body 41 generates an image signal in response to the control command given by the main control unit 3 and outputs the image signal to the display unit 42, so that the display unit 42 displays the animation with the predetermined presentation pattern or the predetermined test image. As shown in FIG. 1, the display device body 41 includes a CPU 411, a VDP (Video Display Processor) 412, a RAM 413, a display program ROM 414, a test program ROM 415 as a test program storing unit, a display buffer 416, and a CGROM 417 as a game image information storing unit. As shown in FIG. 1, the CPU 411, the VDP 412, the RAM 413, the display program ROM 414, the test program ROM 415, the display buffer 416 and the CGROM 417 are respectively connected by buses 418, 419, so that necessary information can be transmitted among the respective components 411 to 415, and among the respective components 412, 416 and 417.

The display program ROM 414 stores the display program in which the display procedures etc. is defined to display the animations with the various presentation patterns on the display unit 42.

The test program ROM 415 stores the image test program for testing the displayed colors etc. of the animation displayed on the display unit 42, and the test image information for testing the displayed colors etc. of the animation displayed on the display unit 42.

The test image information is about the test image for testing whether or not the displayed colors of the animation displayed on the display unit 42 is displayed correctly, and whether or not there is no pixel lacking.

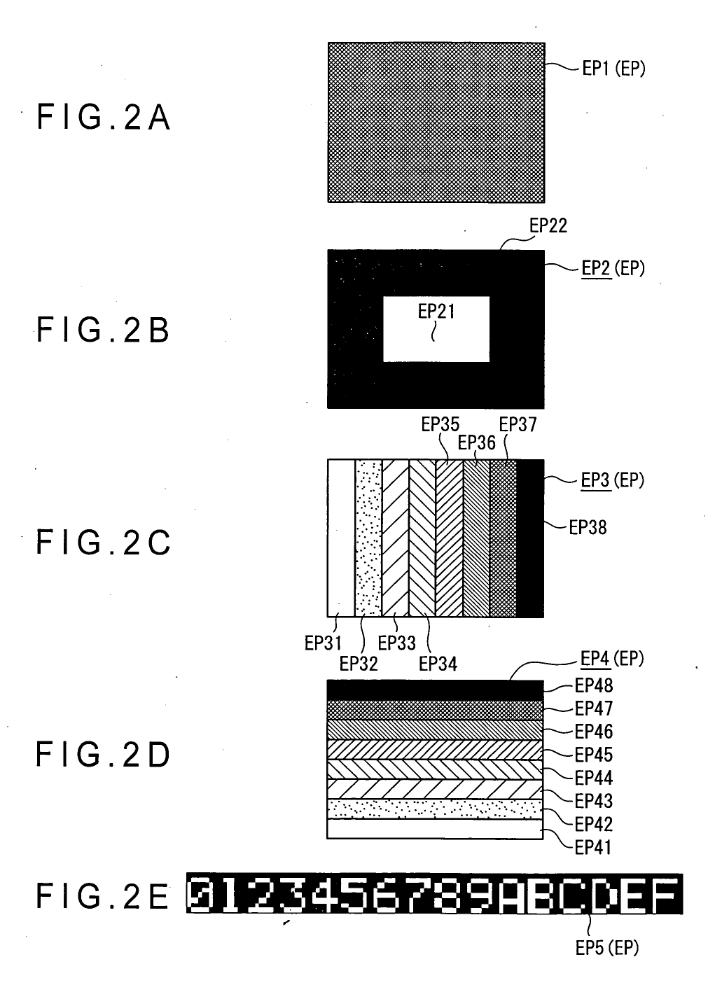

FIGS. 2A to 2E are illustrations respectively showing examples of test image EP.

As shown in FIG. 2A, a test image EP1 is an image entirely formed by a color of red, green, blue or white. For instance, the test image EP1 is used for testing whether or not there is no pixel lacking in the animation displayed on the display unit 42.

As shown in FIG. 2B, a test image EP2 is an image in which a white box EP21 of a predetermined size is formed at the center and a black frame EP22 surrounds the box EP21. For instance, the test image EP2 is used for testing whether or not the position of the animation displayed on the display unit 42 is formed correctly.

As shown in FIG. 2C, a test image EP3 is a so-called vertical color bar in which a “white EP31”, a “yellow EP32”, a “cyan EP33”, a “green EP34”, a “magenta EP35”, a “red EP36”, a “blue EP37”, and a “black EP38” are sequentially formed from the left side to the right side. For instance, the test image EP3 is used for testing whether or not the displayed colors of the animation displayed on the display unit 42 are displayed correctly.

As shown in FIG. 2D, a test image EP4 is a so-called horizontal color bar in which a “white EP41”, a “yellow EP42”, a “cyan EP43”, a “green EP44”, a “magenta EP45”, a “red EP46”, a “blue EP47”, and a “black EP48” are sequentially formed from the lower side to the upper side. For instance, the test image EP4 is used for testing whether or not the displayed colors of the animation displayed on the display unit 42 are displayed correctly in the same manner as the test image EP3.

As shown in FIG. 2E, a test image EP5 is an image in which the numbers of “0” to “9” and the alphabetical characters of “A” to “F” are sequentially formed from the left side to the right side. For instance, according to the test image EP5, the numbers etc. displayed on the display unit 42 are used for displaying information such as ROM checksum test in the test.

Incidentally, the test images are not limited to the above-described test images EP1 to EP5, and may employ, for instance, a so-called gray scale in which the colors of white through black are formed with predetermined gradations (8, 16 or 32 gradations) from the left side to the right side, or a test image in which three colors of red, green and blue are respectively formed with predetermined gradations (16 or 32 gradations) on a single screen.

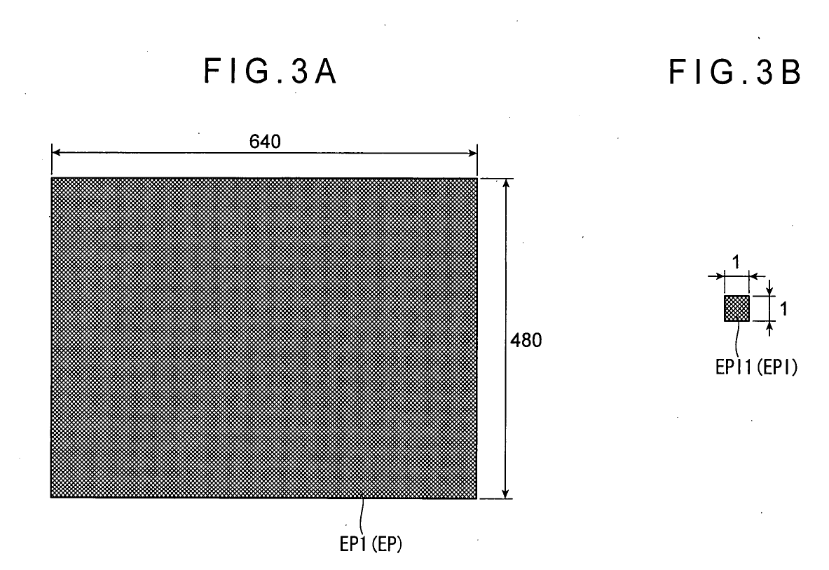

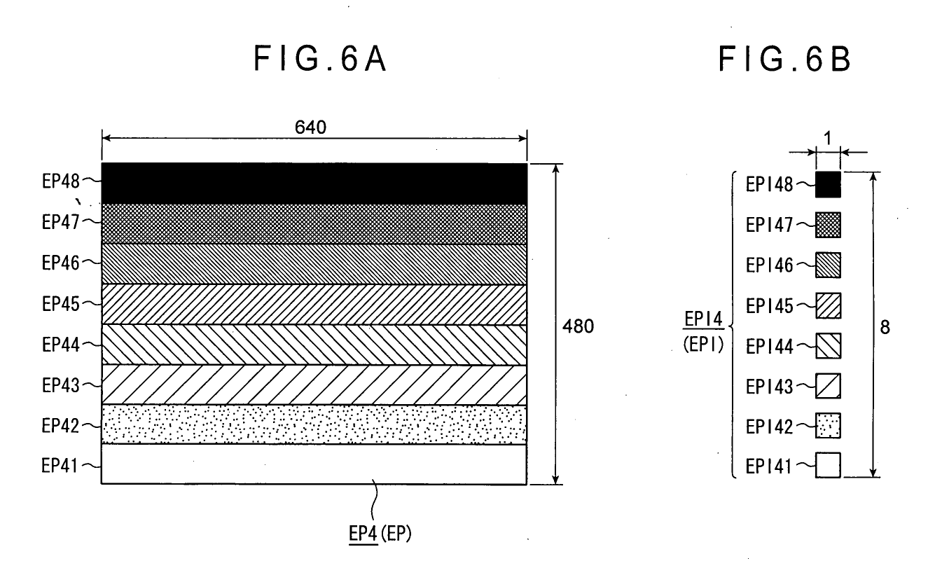

FIGS. 3A and 6B are illustrations respectively showing examples of test image information EP1 stored in the test program ROM 415.

As shown in FIGS. 3A to 6B, predetermined pieces of test image information EPI out of the plural pieces of test image information EPI, are contracted image information with the number of pixels of the test image EP contracted.

For example, as shown in FIGS. 3A and 3B, test image information EPI1 corresponding to the test image EP1 is contracted image information contracted into 1 pixel (1*1 pixel) of the color (red, green, blue or white) of the test image EP1 while the test image EP1 contains 640*480 pixels.

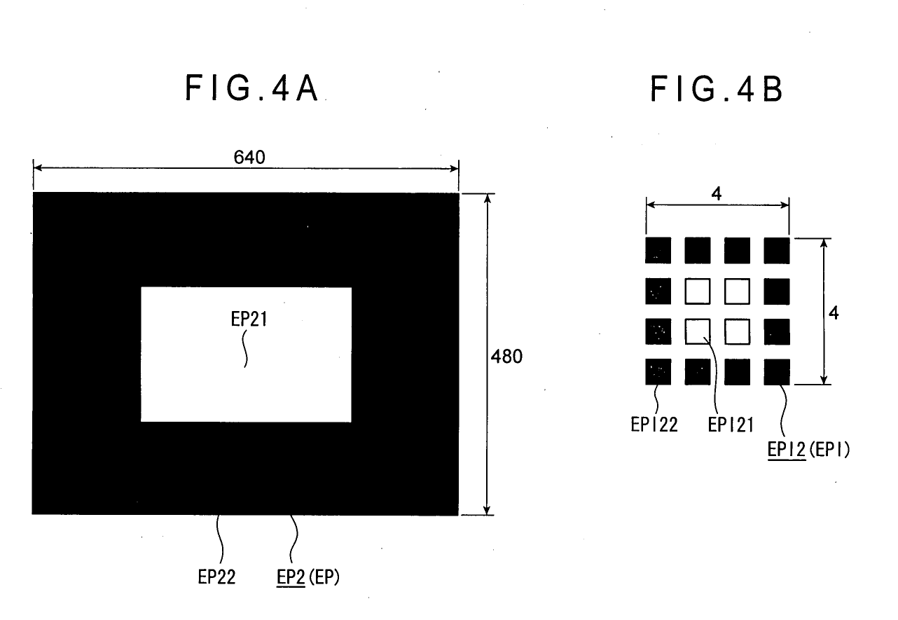

As shown in FIGS. 4A and 4B, test image information EPI2 corresponding to the test image EP2 is contracted image information contracted into 4*4 pixels defined by 4 white pixels EPI21 at the center and 12 black pixels EPI22 surrounding the 4 white pixels EPI21 while the test image EP2 contains 640*480 pixels.

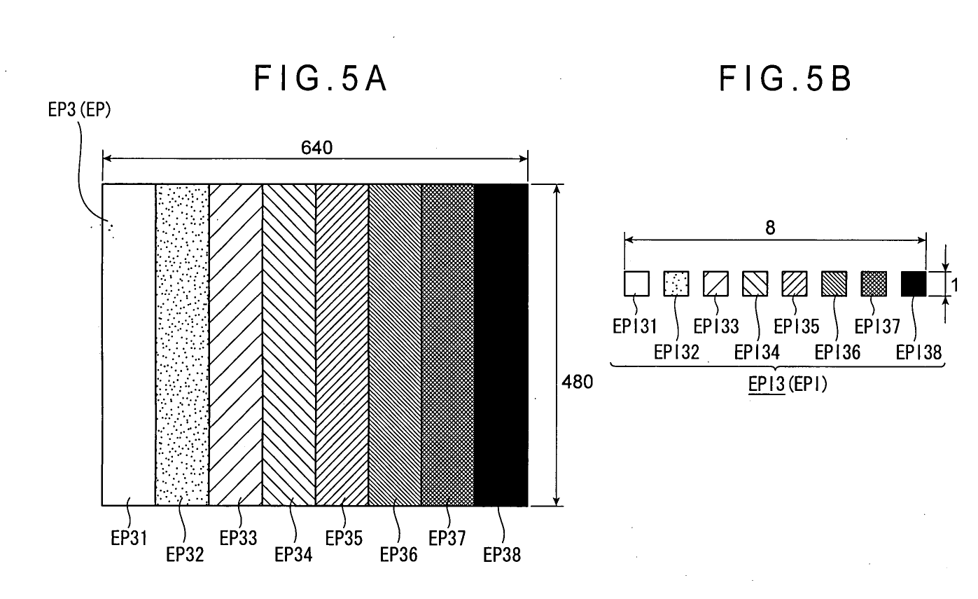

As shown in FIGS. 5A and 5B, test image information EPI3 corresponding to the test image EP3 is contracted image information contracted into 8*1 pixels of pixels EPI31 to EPI38 respectively including the colors (the “white EP31”, the “yellow EP32”, the “cyan EP33”, the “green EP34”, the “magenta EP35”, the “red EP36”, the “blue EP37”, and the “black EP38” are sequentially formed from the left side to the right side) of the test image EP3 while the test image EP3 contains 640*480 pixels.

As shown in FIGS. 6A and 6B, test image information EPI4 corresponding to the test image EP4 is contracted image information contracted into 1*8 pixels of pixels EPI41 to EPI48 respectively including the colors (the “white EP41”, the “yellow EP42”, the “cyan EP43”, the “green EP44”, the “magenta EP45”, the “red EP46”, the “blue EP47”, and the “black EP48” are sequentially formed from the lower side to the upper side) of the test image EP4 in the same manner as the test image information EPI3.

Note that, although the number of pixels for the test image EP is described as 640*480 according to FIGS. 3A to 6B, it is not limited thereto, and other number of pixels can be employed.

The RAM 413 temporarily stores data and program necessary for the operation of the CPU 411.

The CGROM 417 stores plural pieces of game image information related to the character image such as letters and pictures displayed on the three reels (not shown) of the left reel, the central reel and the right reel, and the background image.

The display buffer 416 is a memory in which the VDP 412 virtually draws the animation based on the game image information when the image signal is generated for displaying the various animations.

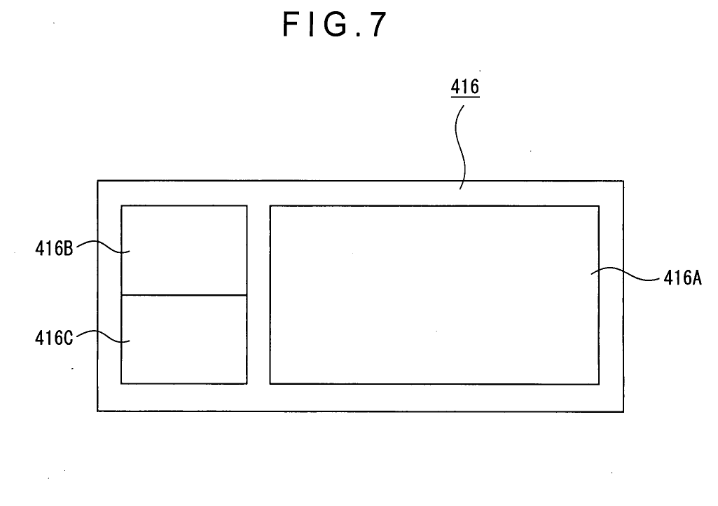

FIG. 7 is a schematic illustration showing an example of the configuration of the display buffer 416.

As shown in FIG. 7, the display buffer 416 includes a temporary image area 416A and two screen buffers 416B, 416C.

The temporary image area 416A temporarily retains the game image information read out from the CGROM 417 or the test image information read out from the test program ROM 415.

The screen buffers 416B, 416C respectively retain the animation or the test image virtually drawn based on the game image information or the test image information temporarily retained in the temporary image area 416A.

The CPU 411 recognizes the control command output from the main control unit 3, reads out the game image information stored in the CGROM 417 or the test image information stored in the test program ROM 415 according to the display program stored in the display program ROM 414 or the image test program stored in the test program ROM 415, and transfers the information to the temporary image area 416A of the display buffer 416 through a transfer buffer (described later) of the VDP 412. And besides, the CPU 411 outputs a display instruction signal (display position, enlargement scale etc.) corresponding to the recognized control command to the VDP 412.

The VDP 412 recognizes the display instruction signal output from the CPU 411 and virtually draws the game image information or the test image information retained in the temporary image area 416A of the display buffer 416 on the screen buffers 416B, 416C of the display buffer 416 so as to generate an image signal based on the animation or the test image and output the signal to the display unit 42. As shown in FIG. 1, the VDP 412 includes a transfer buffer 412A, so that the test image information read out from the test program ROM 415 is transferred to the display buffer 416 through the transfer buffer 412A.

Incidentally, the CPU 411 and the VDP 412 correspond to a control unit of the invention.

The display unit 42 includes a liquid crystal panel and a backlight to display an image with colors, which displays the animation or the test image based on the image signal sent from the VDP 412. Note that, the display unit 42 may not include the liquid crystal panel and the backlight, and may be any configuration as long as the image is displayed with colors. For instance, an organic EL (Electro Luminescence) element or the like may be employed.

Image Test Method of Variable Display Device

Next, an image test method for the above-described variable display device 4 will be described below.

Note that, in the following description, the image test method for the variable display device 4 will mainly be described among the whole operations of the pachinko machine 1, and the description on operations other than the image test method will be omitted.

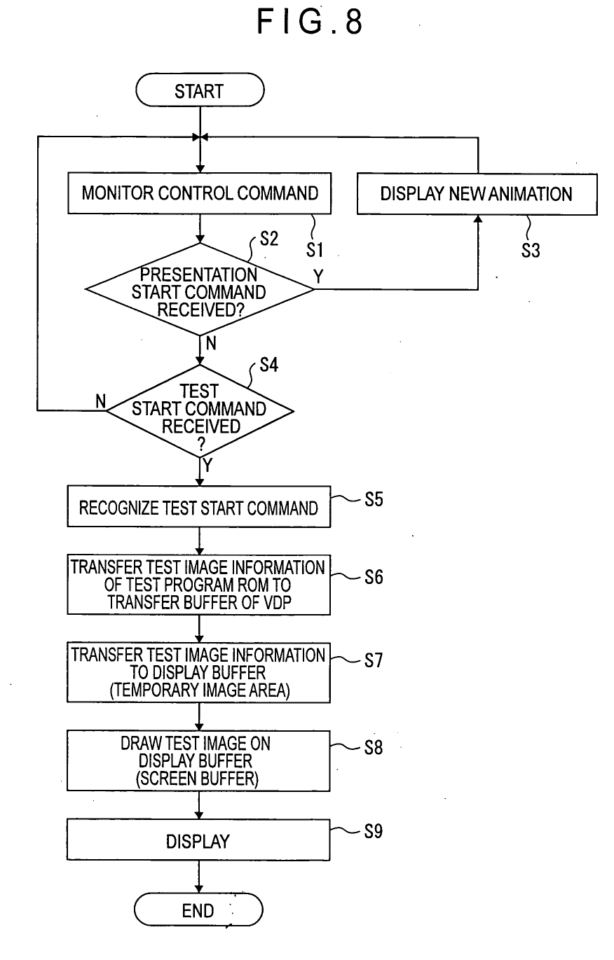

FIG. 8 is a flowchart explaining the image test method for the variable display device 4.

The CPU 411 of the variable display device 4 constantly monitors whether or not the control command is output from the main control unit 3 (step S1).

Additionally in step S1, when the predetermined presentation start command is already output from the main control unit 3 and the variable display device 4 displays the predetermined animation, the variable display device 4 repeatedly displays the predetermined animation until a new control command is output from the main control unit 3.

For instance, in a standby state (when no player exists), the presentation start command is output to the variable display device 4, the command giving the instruction “to display an animation with a predetermined presentation pattern for demonstration (hereinafter, referred to as a demonstration animation) as the animation which is displayed when the power of the pachinko machine 1 is turned on”. Then, the variable display device 4 recognizes the presentation start command, reads out the predetermined game image information from the CGROM 417 according to the display program stored in the display program ROM 414 to draw the read information on the display buffer 416, and controls the display unit 42 to display the demonstration animation. And, the variable display device 4 controls the display unit 42 to repeatedly display the demonstration animation until a new control command is output from the main control unit 3 in step S1.

For instance, in the play state, when the game ball enters the start chucker 22 and a predetermined signal is output from the start chucker 22 to the main control unit 3, the CPU 31 of the main control unit 3 performs a big hit prize lottery, and outputs the presentation start command to the variable display device 4 in accordance with the result of the lottery, the command indicating “to display the animation with a predetermined presentation pattern (hit pattern or miss pattern)”. Then, similar to the above-described manner, the variable display device 4 recognizes the presentation start command, reads out the predetermined game image information from the CGROM 417 according to the display program stored in the display program ROM 414 to draw the read information on the display buffer 416, and controls the display unit 42 to display the animation with the hit pattern or the miss pattern. And, the variable display device 4 controls the display unit 42 to repeatedly display the animation until a new control command is output from the main control unit 3 in step S1.

In step S1, the variable display device 4 judges whether or not the control command is the presentation start command when recognizing the output of the new control command from the main control unit 3 (step S2).

In step S2, when judging as “Y”, i.e., when judging that the new control command given by the main control unit 3 is the presentation start command, the variable display device 4 recognizes the presentation start command and controls the display unit 42 to display the animation with a new presentation pattern according to the presentation start command (step S3). The variable display device 4 then returns to step S1 to control the display unit 42 to repeatedly display the animation until a new control command is output from the main control unit 3.

On the other hand, in step S2, when judging as “N”, i.e., when judging that the new control command given by the main control unit 3 is not the presentation start command, the variable display device 4 judges whether or not the control command is the test start command (step S4).

In step S4, when judging as “N”, i.e., when judging that the new control command given by the main control unit 3 is not the test start command, the variable display device 4 returns to step S1 again. Note that, the main control unit 3 outputs various control commands other than the presentation start command and the test start command. The present exemplary embodiment, as stated above, mainly describes the image test method for the variable display device 4, and omits other operations corresponding to the control commands other than the presentation start command and the test start command.

On the other hand, in step S4, when judging as “Y”, i.e., when judging that the new control command given by the main control unit 3 is the test start command, the variable display device 4 recognizes the test start command (step S5: inputting step).

After step S5, the CPU 411 of the variable display device 4 reads out from the test program ROM 415 the test image information corresponding to the test start command recognized in the inputting step S5 according to the image test program stored in the test program ROM 415, transfers the read test image information to the transfer buffer 412A of the VDP 412 (step S6), and transfers the information further to the temporary image area 416A of the display buffer 416 (step S7). Incidentally, a step of reading the image information according to the invention corresponds to step S6 and step S7 described above.

Then, the CPU 411 outputs a display instruction signal corresponding to the test start command recognized in the inputting step S5 to the VDP 412.

After step S7, the VDP 412 enlarges the test image information retained in the temporary image area 416A into the test image containing the predetermined number of pixels according to the display instruction signal given by the CPU 411, and virtually draws the enlarged test image on the screen buffers 416B, 416C so that the test image is located at a predetermined display position (step S8). Then, the VDP 412 generates an image signal based on the test image and outputs the signal to the display unit 42. The display unit 42 displays the test image with colors according to the image signal sent from the VDP 412 (step S9). Incidentally, the step of displaying according to the invention corresponds to step S8 and step S9 described above.

Accordingly, an operator tests the displayed colors etc. of the animation displayed on the display unit 42 by checking the test image displayed on the display unit 42 by checking the image, for instance, with eyes.

As described above, in the present exemplary embodiment, the game image information is stored in the CGROM 417 while the test image information EPI is stored in the test program ROM 415, so that the storage location of the game image information is independent from that of the test image information EPI. Therefore, even when the game image information is corrected or modified, the storage address of the test image information EPI will not be changed, and consequently, the image test program need not be corrected. In addition, since the game image information can independently be produced from the image test program, when a new model pachinko machine 1 is developed, the image test program can be developed before the production of the game image information is completed. Accordingly, with the image test method of the present exemplary embodiment, the image test program can easily be produced.

In addition, since the storage location of the game image information is independent from that of the test image information EPI, the storage address of the game image information will not be changed even when the test image information EPI is additionally provided or modified, so that it is not necessary to correct the display program for instructing the display unit to display the game image based on the game image information.

Further, since the test image information EPI and the image test program are stored in the test program ROM 415, preparing the test program ROM 415 only for one model is enough to perform the image test of the variable display device 4 of the various model pachinko machines 1 having different kinds of game image information, simply by replacing the test program ROM 415.

In the plural pieces of test image information EPI, since the test image information EPI1 to EPI4 respectively have the contracted image information in which the number of pixels of the test images EP1 to EP4 are contracted, the size of the test image information EPI can be decreased, and thus the capacity of the test program ROM 415 need not be increased. In addition, by decreasing the size of the test image information EPI, the data transmission of the test image information EPI via the busses 418, 419 can be performed smoothly, thereby quickly displaying the test image EP on the display unit 42.

It is to be understood that the invention is not limited to the above-described exemplary embodiment, and includes modifications and improvements without departing from the scope of the invention.

In the above-described exemplary embodiment, the pachinko machine 1 is employed as the game machine, and the image test for the variable display device 4 in the pachinko machine 1 is described, however, it is not limited thereto. The invention can be employed for the image test of a variable display device in pinball-slot combination machines and other game machines.

In the above-described exemplary embodiment, the image test program is stored in the test program ROM 415, it is not limited thereto. The image test program may be stored in a recording medium connectable to the variable display device 4 and readable by the display device body 41 of the variable display device 4. In this case, the image test program can easily be distributed. In addition, the test image program can even be distributed via the Internet etc.

The image test method of the invention can be used as an image test method for a game machine display device because the image test program can easily be produced.

What is claimed is:

1. An image test method for a game machine display device provided with a display unit that displays a predetermined image, a game image information storing unit that stores game image information, a control unit that instructs the display unit to display a game image based on the game image information, and a test program storing unit that stores an image test program for testing the game image displayed on the display unit, the test program storing unit storing test image information for testing the game image displayed on the display unit in addition to the image test program, the method under the control of the control unit comprising the steps of:
inputting a control command to start a test of an image;
reading out the test image information from the test program storing unit; and
displaying the test image based on the test image information on the display unit.

2. The image test method according to claim 1, wherein
the test image information is contracted image information in which the number of pixels of the test image is contracted, and
in displaying, the control unit enlarges the contracted image information and controls the display unit to display the test image.

3. An image test program for a game machine display device provided with a display unit that displays a predetermined image, a game image information storing unit that stores game image information, a control unit that instructs the display unit to display a game image based on the game image information, and a test program storing unit that stores an image test program and test image information for testing the game image displayed on the display unit, the test program storing unit storing test image information for testing the game image displayed on the display unit in addition to the image test program, the program instructing the control unit to execute instructions, comprising the steps of:
inputting a control command to start a test of an image;
reading out the test image information from the test program storing unit; and
displaying the test image based on the test image information on the display unit.

4. The image test program according to claim 3, wherein
the test image information is contracted image information in which the number of pixels of the test image is contracted, and
in displaying, the control unit enlarges the contracted image information and controls the display unit to display the test image.

5. A recording medium storing readably by a computing unit an image test program for a game machine display device provided with a display unit that displays a predetermined image, a game image information storing unit that stores game image information, a control unit that instructs the display unit to display a game image based on the game image information, and a test program storing unit that stores an image test program and test image information for testing the game image displayed on the display unit, the test program storing unit storing test image information for testing the game image displayed on the display unit in addition to the image test program, the program instructing the control unit to execute instructions, comprising the steps of:
inputting a control command to start a test of an image;
reading out the test image information from the test program storing unit; and
displaying the test image based on the test image information on the display unit.

6. The recording medium storing the image test program according to claim 5, wherein
the test image information is contracted image information in which the number of pixels of the test image is contracted, and
in displaying, the control unit enlarges the contracted image information and controls the display unit to display the test image.
